(19) United States
(12) Patent Application Publication
(10) Pub. No.: US 2002/0072185 A1
(43) Pub. Date: Jun. 13, 2002

(54) Method of forming gate structure

(76) Inventor: Wei Wen Chen, Hsinchu (TW)

Correspondence Address: J.C. Patents, Inc., 4 IRVINE, SUITE 250, Irvine, CA, 92618, US

(21) Appl. No.: 09/777,254

(22) Filed: Feb. 5, 2001

(30) Foreign Application Priority Data
Dec. 8, 2000 (TW) 89126179

(51) Int. Cl. H01L 21/336; H01L 21/8238; H01L 21/3205; H01L 21/4763; H01L 21/31; H01L 21/469

(52) U.S. Cl. 438/305; 438/595; 438/303; 438/299; 438/231; 438/766; 438/771

(57) ABSTRACT

A method of forming a gate structure. A gate dielectric layer and a polysilicon gate are sequentially formed over a substrate. The substrate is enclosed within a chamber and surrounded by oxygen-containing plasma. A negative voltage is applied to the substrate so that the oxygen ions of the oxygen-containing plasma are implanted into a superficial layer of the polysilicon gate. An annealing operation is conducted in an inert atmosphere so that the implanted oxygen ions in the polysilicon gate react with silicon to form a silicon oxide buffer layer. Finally, spacers are formed on the external sidewall of the silicon oxide buffer layers next to the polysilicon gate.

### CROSS-REFERENCE TO RELATED APPLICATION

This application claims the priority benefit of Taiwan application serial no. 89126179, filed Dec. 8, 2000.

### BACKGROUND OF THE INVENTION

1. Field of Invention

The present invention relates to a method of manufacturing a semiconductor device. More particularly, the present invention relates to a method of forming a gate structure.

2. Description of Related Art

Metal-oxide-semiconductor (MOS) transistors are a common semiconductor device. Switching of the MOS transistor is achieved by applying a voltage to its gate terminal. A gate oxide layer normally separates the gate terminal from a substrate. Thickness and quality of the gate oxide layer has important influence on the electrical properties of the transistor. In most semiconductor fabrication, spacers are generally formed on the sidewalls of the polysilicon gate to serve as an isolation layer so that short-circuiting between the polysilicon gate and the subsequently formed source/drain region or contact is prevented. Typically, the spacers are made from silicon nitride material. However, because of the greater stress between silicon nitride material and polysilicon material, a silicon oxide layer is formed over the polysilicon gate serving as a buffer layer before the spacers are formed. This is the so-called silicon oxide buffer layer.

Conventional methods of forming the silicon oxide buffer layer include thermal oxidation and chemical vapor deposition (CVD). In thermal oxidation, a wafer is placed inside a reaction chamber. Oxygen is passed into the reaction chamber and at the same time heated, to oxidize the surface of the polysilicon gate. In chemical vapor deposition, silane (SiH₄) and oxygen (O₂) are passed into the reaction chamber to form a silicon nitride buffer layer. Alternatively, silane/O₂/NH₃ are passed into the reaction chamber to form a silicon oxynitride buffer layer.

Since thermal oxidation is conducted at a high temperature, oxygen may easily diffuse into the polysilicon gate and react with silicon there. Hence, the critical dimension of the polysilicon gate will be reduced considerably. In addition, oxygen may also diffuse into the upper and lower portion of the gate oxide layer and react with material in the polysilicon/silicon substrate to form a thick bird's beak on each side of the gate oxide layer. Because thickness of the gate oxide layer has a great influence on the electrical properties of the device, the formation of a bird's beak may result in some difficulty in transistor control. Moreover, the thickness of the silicon oxide buffer layer on the substrate on each side of the gate formed by thermal oxidation is difficult to reduce. Consequently, a big height difference is created between the tip section of the source/drain extension region and the tip section of the substrate underneath the gate oxide layer. Therefore, the device channel may deviate from the ideal surface channel of a transistor.

Chemical vapor deposition, on the other hand, is a process conducted at a high temperature using silane (SiH₄) and oxygen (O₂) (or with the addition of ammonia (NH3)) as gaseous reactants to deposit silicon oxide or silicon oxynitride. Hence, oxygen may easily diffuse into the polysilicon layer and react with the polysilicon material leading to a considerable reduction of the critical dimensions of the polysilicon gate.

### SUMMARY OF THE INVENTION

Accordingly, one object of the present invention is to provide a method of forming a gate structure. First, a gate dielectric layer and a polysilicon gate are sequentially formed over a substrate. The substrate is enclosed within a chamber and surrounded by oxygen-containing plasma. A negative voltage is applied to the substrate so that the oxygen ions of the oxygen-containing plasma are implanted into a superficial layer of the polysilicon gate. An annealing operation is conducted in an inert atmosphere so that the implanted oxygen ions in the polysilicon gate surface layer can react with silicon to form a silicon oxide buffer layer. Finally, spacers are formed on the exterior sidewall of the silicon oxide buffer layers next to the polysilicon gate.

According to the aforementioned method of forming the gate structure, oxygen-containing plasma is used to implant oxygen ions into a surface layer of the polysilicon gate followed by an annealing operation to form the silicon oxide buffer layer. Because the energy level of the oxygen ions inside the plasma can be tuned by adjusting the negative voltage, the thickness of the silicon oxide buffer layer can be finely controlled. Hence, excessive reduction of the critical dimension of a gate can be prevented. In addition, the process of forming the oxygen-containing plasma does not require a high temperature. Therefore, very few oxygen atoms will diffuse into the upper and lower portion of the gate oxide layer and a bird's beak will not form on each side of the gate oxide layer. Hence, electrical characteristics of the device will be little affected. Moreover, because the energy level of the oxygen ions in the plasma can be precisely controlled by the negative voltage, thickness of the silicon oxide buffer layer above the source/drain region can be reduced to a minimum. Consequently, step height between the tip section of the source/drain extension region and the tip section of the substrate underneath the gate oxide layer is reduced leading to a closer resemblance to an ideal surface channel of a transistor.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1D are schematic cross-sectional views showing the progression of steps for producing the gate structure of a MOS transistor according to one preferred embodiment of this invention.

### DESCRIPTION OF THE PREFERRED EMBODIMENTS

Reference will now be made in detail to the present preferred embodiments of the invention, examples of which are illustrated in the accompanying drawings.

Wherever possible, the same reference numbers are used in the drawings and the description to refer to the same or like parts.

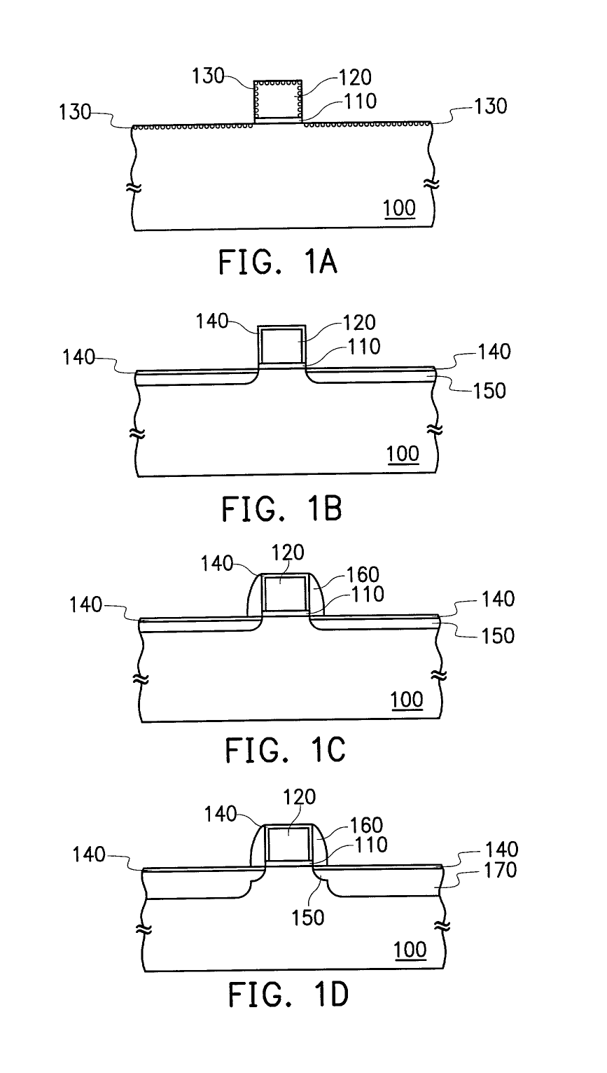

FIGS. 1A through 1D are schematic cross-sectional views showing the progression of steps for producing the gate structure of a MOS transistor according to one preferred embodiment of this invention.

As shown in FIG. 1A, a substrate 100 is provided. A gate oxide layer 110 and a polysilicon gate 120 are sequentially formed over the substrate 100. The substrate 100 is placed inside a reaction chamber filled with pure oxygen plasma or nitrogen/oxygen plasma. Meanwhile, a negative voltage is applied to the substrate 100 so that the oxygen ions 130 of the pure oxygen or nitrogen/oxygen plasma are implanted into the polysilicon gate 120 and the exposed substrate 100 surface. The amount of oxygen within the nitrogen/oxygen plasma is between 1% to 100% while oxygen ions of the pure oxygen or nitrogen/oxygen plasma have an average energy of between 200 eV to 5000 eV. The dosage of oxygen ions implanted into the substrate 100 is greater than 10¹⁷/cm².

As shown in FIG. 1B, the substrate is surrounded by an inert atmosphere such as a nitrogen atmosphere and an annealing operation is performed. Ultimately, the implanted oxygen in a surface layer of the polysilicon gate 120 and the substrate 100 can react with silicon to form a silicon oxide buffer layer 140. The silicon oxide buffer layer 140 has a thickness between 50 Å to 200 Å. The annealing operation is carried out at a temperature between about 700° C. to 1000° C., for example, in a rapid thermal annealing process. Using the polysilicon gate 120 as a mask, a lightly doped drain (LDD) region 150 is formed in the substrate 100 on each side of the polysilicon gate 120.

As shown in FIG. 1C, silicon nitride spacers 160 are formed on the external sidewall of the silicon oxide buffer layer 140 next to the polysilicon gate 120. The silicon oxide buffer layer 140 serves as a transition layer that reduces the level of stress between the spacers 160 and the polysilicon gate 120.

As shown in FIG. 1D, using the polysilicon gate 120 and the silicon nitride spacers 160 as a mask, ions are implanted into the substrate 100 on each side of the silicon nitride spacers 160 to form source/drain regions 170.

According to the aforementioned method of forming the gate structure, oxygen-containing plasma is used to implant oxygen ions into a superficial layer of the polysilicon gate 120. This is followed by an annealing operation to form the silicon oxide buffer layer 140. The advantages of this invention includes:

1. Since implantation energy of the oxygen ions can be adjusted by changing the applied negative voltage to the substrate, a silicon oxide buffer layer 120 with minimal thickness can be formed. Hence, there is very little reduction of the critical dimension of the polysilicon gate 140.

2. Since no high temperature is required to form the oxygen-containing plasma, oxygen will not diffuse into the upper and lower surface layer of the gate oxide layer 110. Hence, no bird's beak that may lead to a deterioration of electrical properties is formed on each side of the gate oxide layer 110.

3. Due to the precise adjustment of the energy level of oxygen ions in the plasma by changing the negative voltage applied to the substrate 100, the silicon oxide buffer layer 140 above the lightly doped drain 150 can have a minimal thickness. Therefore, step height between the tip section of the lightly doped drain 150 and the tip section of the substrate 100 underneath the gate oxide layer 110 can be reduced so that the channel of a device can be closer to an ideal surface channel.

In addition, this invention can be applied to any process that demands the formation of spacers on a polysilicon conductive line, not just a polysilicon gate. Polysilicon conductive lines, for example, include the bit lines of dynamic random access memory. Spacers may be required on each side of the bit line to prevent the short-circuiting of the bit line with a neighboring node contact. Hence, if the method of forming a silicon oxide buffer layer is employed, minimal reduction of the critical dimension of a polysilicon bit line may be achieved. Moreover, the conditions of formation and thickness of the silicon oxide buffer layer on the polysilicon bit line are almost identical to those described in the aforementioned preferred embodiment of this invention.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of forming a gate over a substrate, comprising the steps of:
sequentially forming a gate dielectric layer and a polysilicon gate over the substrate;
surrounding the substrate with an oxygen-containing plasma;
applying a negative voltage to the substrate so that oxygen ions of the oxygen-containing plasma are implanted into a superficial layer of the polysilicon gate;
performing an annealing operation of the substrate in an inert atmosphere so that the implanted oxygen inside the polysilicon gate can react with silicon to form a silicon oxide buffer layer; and
forming spacers on the exterior sidewall of the silicon oxide buffer layer that joins with the sidewall of the polysilicon gate.

2. The method of claim 1, wherein the step of forming the spacers includes depositing silicon nitride.

3. The method of claim 1, wherein the gate dielectric layer includes a gate oxide layer.

4. The method of claim 1, wherein the oxygen-containing plasma includes pure oxygen plasma or nitrogen/oxygen plasma, and the oxygen content within the nitrogen/oxygen plasma is greater than 1% but smaller than 100%.

5. The method of claim 1, wherein the inert atmosphere includes an atmosphere of nitrogen.

6. The method of claim 1, wherein the oxygen ions within the oxygen-containing plasma have an average energy level between 200 eV to 5000 eV.

7. The method of claim 1, wherein a dosage of the oxygen ions within oxygen-containing plasma greater than 10¹⁷/cm² is implanted into the substrate.

8. The method of claim 1, wherein the silicon oxide buffer layer has a thickness between about 50 Åto 200 Å.

9. The method of claim 1, wherein the annealing operation is conducted at a temperature between about 700° C. to 1000° C.

10. The method of claim 1, wherein the annealing operation includes a rapid thermal annealing.

11. A method of forming a polysilicon conductive line over a substrate, comprising the steps of:
forming a polysilicon conductive line over the substrate;
surrounding the substrate with an oxygen-containing plasma;
applying a negative voltage to the substrate so that oxygen ions of the oxygen-containing plasma are implanted into a superficial layer of the polysilicon conductive line;
performing an annealing operation of the substrate in an inert atmosphere so that the implanted oxygen inside the polysilicon conductive line can react with silicon to form a silicon oxide buffer layer; and
forming spacers on the exterior sidewall of the silicon oxide buffer layer that joins with the sidewall of the polysilicon conductive line.

12. The method of claim 11, wherein the step of forming the spacers includes depositing silicon nitride.

13. The method of claim 11, wherein the oxygen-containing plasma includes pure oxygen plasma or nitrogen/oxygen plasma, and the oxygen content within the nitrogen/oxygen plasma is greater than 1% but smaller than 100%.

14. The method of claim 11, wherein the inert atmosphere includes an atmosphere of nitrogen.

15. The method of claim 11, wherein the oxygen ions within the oxygen-containing plasma has an average energy level between 200 eV to 5000 eV.

16. The method of claim 11, wherein a dosage of the oxygen ions within oxygen-containing plasma greater than 10¹⁷/cm² is implanted into the substrate.

17. The method of claim 11, wherein the silicon oxide buffer layer has a thickness between about 5 Å to 200 Å.

18. The method of claim 11, wherein the annealing operation is conducted at a temperature between about 700° C. to 1000° C.

19. The method of claim 11, wherein the annealing operation includes a rapid thermal annealing.
